(19) United States
(12) Patent Application Publication
(10) Pub. No.: US 2026/0313897 A1
(43) Pub. Date: Oct. 8, 2026

(54) MICROELECTRONIC DEVICES, AND RELATED METHODS AND MEMORY DEVICES

(71) Applicant: Micron Technology, Inc., Boise, ID (US)

(72) Inventors: Haitao Liu, Boise, ID (US); Kunal R. Parekh, Boise, ID (US); Chandra V. Mouli, Boise, ID (US)

(21) Appl. No.: 19/563,707

(22) Filed: Mar. 11, 2026

Related U.S. Application Data
(60) Provisional application No. 63/785,346, filed on Apr. 8, 2025.

(51) Int. Cl. H10B 43/27; H10B 43/30; H10B 80/00; H10D 30/01; H10D 30/69; H10D 62/17; H10D 80/30; H10W 90/00

(52) U.S. Cl. CPC H10B 43/27; H10B 43/30; H10D 30/0413; H10D 30/693; H10B 80/00; H10D 62/235; H10D 80/30; H10W 90/792

(57) ABSTRACT

A microelectronic device includes a stack structure, a cell pillar structure, metal material, and additional metal material. The stack structure includes tiers vertically stacked relative to one another and respectively including conductive material and insulative material vertically neighboring the conductive material. The cell pillar structure extends through the stack structure and includes a fill material, a channel material, and an outer material stack. The metal material and the additional metal material are above the conductive material of an uppermost one of the tiers of the stack structure, and are respectively in physical contact with the channel material of the cell pillar structure. The metal material has a work function within a range of from about 3.6 eV to about 4.7 eV. The additional metal material has an additional work function within a range of from about 4.4 eV to about 5.3 eV. Related methods and memory devices are also described.

### CROSS-REFERENCE TO RELATED APPLICATIONS

This application claims the benefit under 35 U.S.C. § 119(e) of U.S. Provisional Patent Application Ser. No. 63/785,346, filed Apr. 8, 2025, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more decks (e.g., stack structures) including tiers of conductive structures and dielectric materials. Each vertical memory string may include at least one select device coupled in series to a serial combination of vertically stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Some peripheral devices (e.g., control logic devices) within a peripheral circuitry region of a memory device underlying or overlying a memory array of the memory device (e.g., a non-volatile memory device) have been used to control operations (e.g., access operations, read operations, write operations, erase operations) on the memory cells of the memory device. An assembly of peripheral devices (e.g., control logic devices) within a peripheral circuitry region may be provided in electrical communication with the memory cells of the memory array by way of routing and interconnect structures. However, processing conditions (e.g., temperatures, pressures, materials) and/or designs for the formation of the memory array over the peripheral circuitry region can limit the configurations and performance of the at least some of the peripheral devices within the peripheral circuitry region; or processing conditions and/or designs for the formation of the peripheral circuitry region outside horizontal boundaries of the memory array can limit the configurations and performance of features of the memory array. In addition, conventional memory device configurations can also be complex and costly to manufacture, can impede reductions to the size (e.g., horizontal footprint) of a memory device, and/or can impede improvements in the performance (e.g., faster memory cell ON/OFF speed, lower threshold switching voltage requirements, faster data transfer rates, lower power consumption) of the memory device.

### BRIEF DESCRIPTION OF THE DRAWINGS

FIGS. 1A through 1F are simplified, partial vertical cross-sectional views illustrating a method of forming a microelectronic device, in accordance with embodiments of the disclosure.

FIG. 2 is a simplified, partial vertical cross-sectional view of a microelectronic device, in accordance with additional embodiments of the disclosure.

FIG. 3 is a simplified, partial vertical cross-sectional view of a microelectronic device, in accordance with further embodiments of the disclosure.

FIG. 4 is a schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, a “semiconductor structure” or a “semiconductor structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

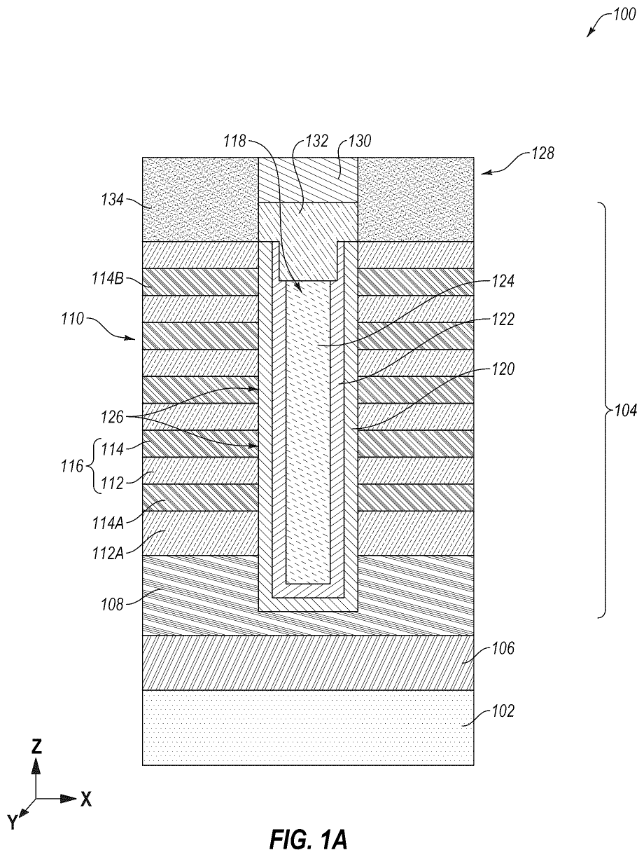

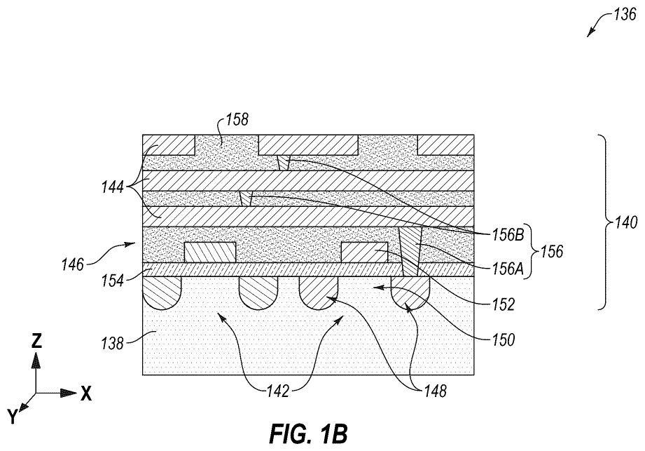

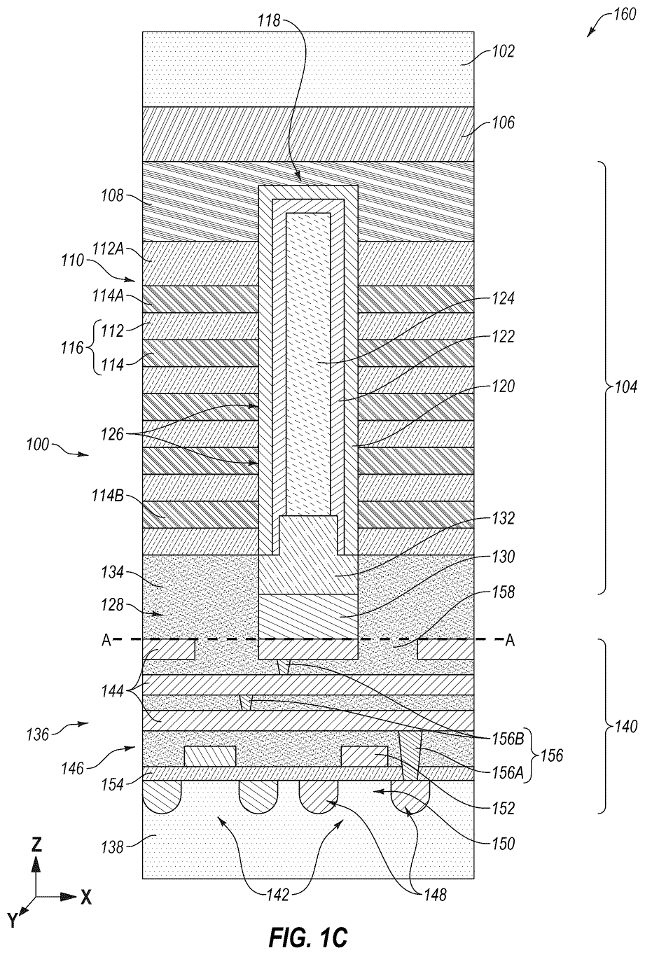

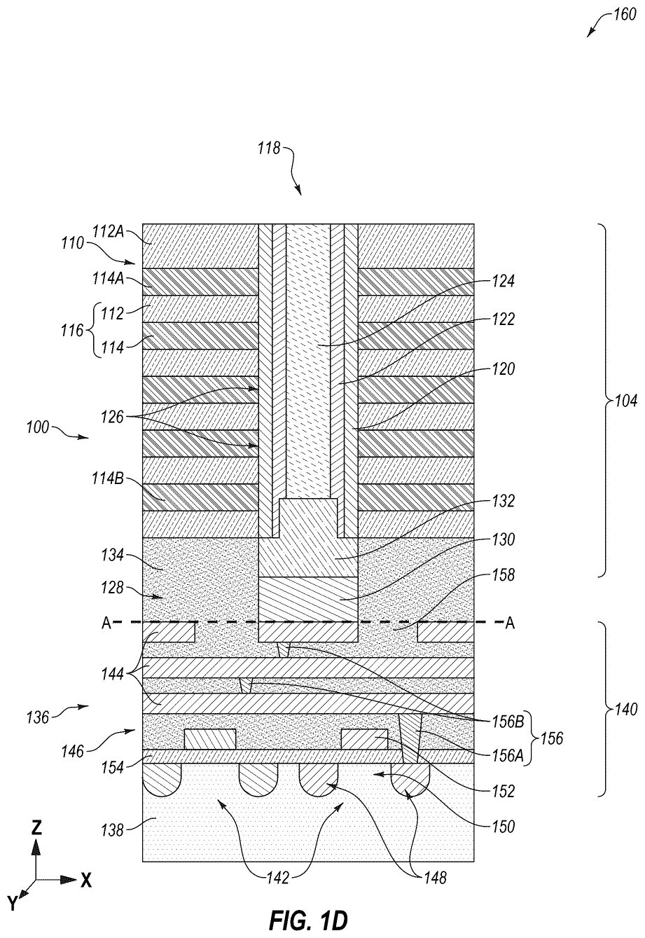

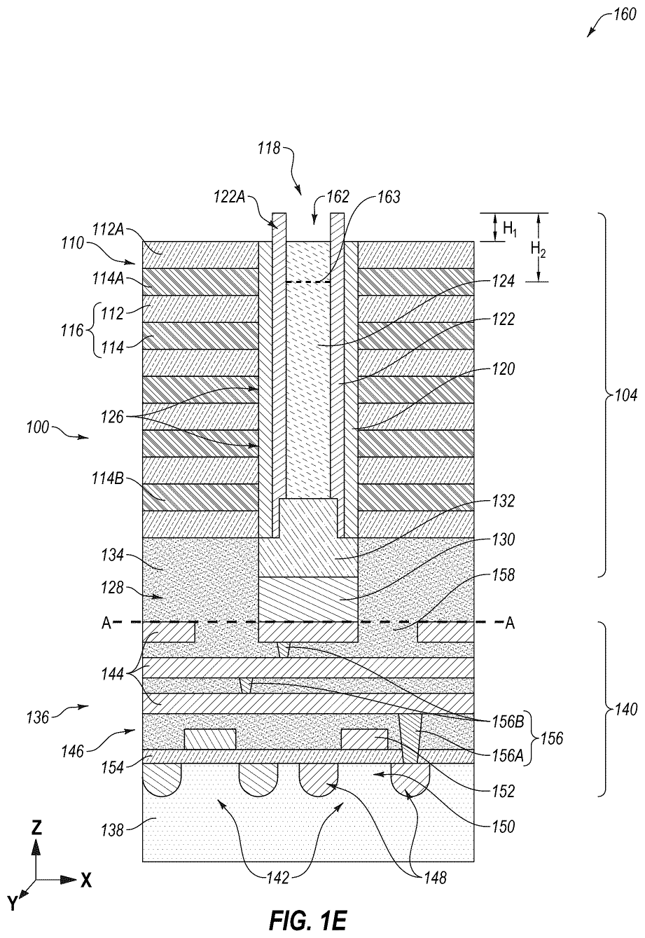

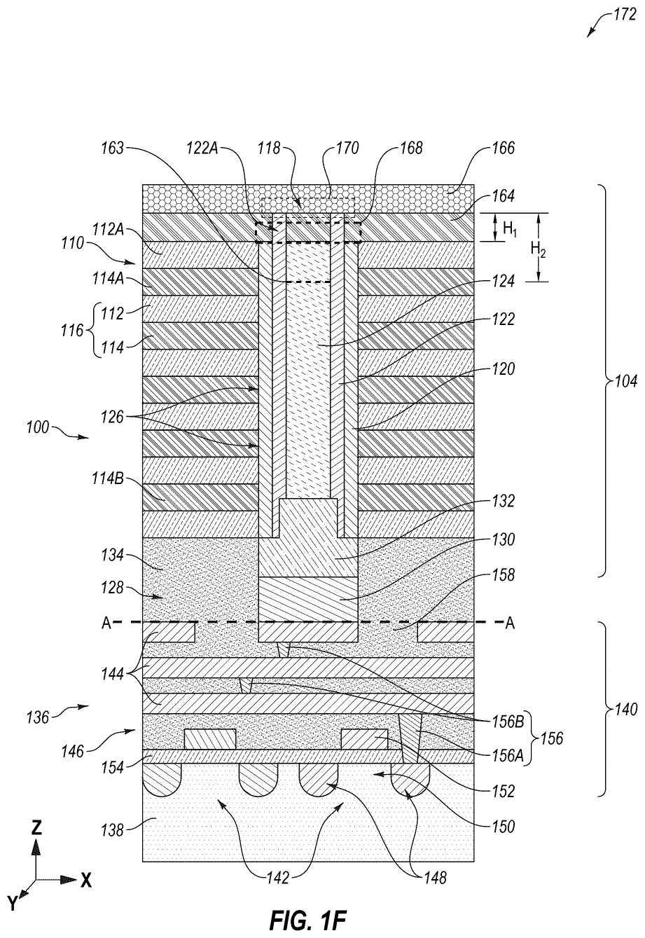

FIGS. 1A through 1F are simplified, partial vertical cross-sectional views illustrating embodiments of a method of forming a microelectronic device (e.g., a memory device, such as a 3D NAND Flash memory device). With the description provided below, it will be readily apparent to one of ordinary skill in the art that the methods and structures described herein may be used to form various devices and electronic systems.

Referring to FIG. 1A, a first microelectronic device structure 100 (e.g., a first wafer, a memory array wafer) may be formed to include a base structure 102, and a memory array region 104 over the base structure 102. The memory array region 104 includes a first isolation material 106 on or over the base structure 102; semiconductor material 108 on or over the first isolation material 106; a stack structure 110 on or over the semiconductor material 108; cell pillar structures 118 vertically extending (e.g., in the Z-direction) through the stack structure 110 and into the semiconductor material 108; at least one conductive routing tier 128 overlying the stack structure 110, and including conductive routing structures 130 coupled to the cell pillar structures 118; and a second isolation material 134 on or over the stack structure 110 and at least partially surrounding (e.g., horizontally surrounding) the conductive routing structures 130. A source side of the memory array region 104 may be considered to be a first vertical boundary (e.g., a first end) most proximate to the semiconductor material 108, and a drain side of the memory array region 104 may be considered to be a second vertical boundary (e.g., a second end) most proximate to the conductive routing tier 128 including the conductive routing structures 130. The first microelectronic device structure 100 (including the base structure 102 and the memory array region 104 thereof) also includes additional features (e.g., structures, materials, devices), as described in further detail below.

The base structure 102 of the first microelectronic device structure 100 comprises a base material or construction upon which additional features (e.g., materials, structures, devices) of the first microelectronic device structure 100 are formed. The base structure 102 may, for example, be formed of and include one or more of semiconductor material, a base semiconductor material on a supporting structure, glass material (e.g., one or more of borosilicate glass (BSP), phosphosilicate glass (PSG), fluorosilicate glass (FSG), borophosphosilicate glass (BPSG), aluminosilicate glass, an alkaline earth boro-aluminosilicate glass, quartz, titania silicate glass, and soda-lime glass), and ceramic material (e.g., one or more of poly-aluminum nitride (p-AlN), silicon on poly-aluminum nitride (SOPAN), aluminum nitride (AlN), aluminum oxide (e.g., sapphire; α-Al₂O₃), and silicon carbide). The base structure 102 may be configured to facilitate safe handling of the first microelectronic device structure 100 for subsequent attachment to a second microelectronic device structure, as described in further detail below. In some embodiments, the base structure 102 is a semiconductor structure (e.g., a silicon structure, such as a polycrystalline silicon structure). In additional embodiments, the base structure 102 is one of a glass structure and a ceramic structure. The base structure 102 may include one or more layers, structures, and/or regions formed therein and/or thereon.

The first isolation material 106 may be formed of and include insulative material. By way of non-limiting example, the first isolation material 106 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), and at least one dielectric carboxynitride material (e.g., SiOₓC_{z}N_{y}). In some embodiments, the first isolation material 106 is formed of and includes dielectric oxide material (e.g., SiOₓ, such as SiO₂). The first isolation material 106 may be substantially homogeneous, or the first isolation material 106 may be heterogeneous.

The semiconductor material 108 may be doped or may be substantially undoped. In some embodiments, the semiconductor material 108 is formed of and includes substantially undoped polycrystalline silicon (also referred to herein as “polysilicon”). In additional embodiments, the semiconductor material 108 is formed of and includes polycrystalline silicon doped (e.g., impregnated) with one or more conductivity enhancing species (e.g., one or more N-type dopants, one or more P-type dopants). For example, the semiconductor material 108 may be formed of and include polycrystalline silicon doped (e.g., relatively highly doped) with at least one N-type dopant (e.g., one or more of phosphorus, arsenic, antimony, and bismuth). As another example, the semiconductor material 108 may be formed of and includes polycrystalline silicon doped (e.g., relatively highly doped) with at least one P-type dopant (e.g., one or more of boron, aluminum, and gallium).

The first microelectronic device structure 100 may be formed to be free of (e.g., to not include) any conductive, lateral contact structure interposed between the base structure 102 and the stack structure 110 (e.g., between the semiconductor material 108 and the stack structure 110), wherein the cell pillar structures 118 vertically extend completely through the conductive, lateral contact structure and channel material 122 (described in further detail below) of individual cell pillar structures 118 contacts (e.g., physically contacts, electrically contacts) the conductive, lateral contact structure. The omission (e.g., absence) of such a conductive, lateral contact structure may decrease processing complexity and increase production efficiency as compared to conventional methods and conventional designs employing such a conductive, lateral contact structure.

Still referring to FIG. 1A, the stack structure 110 within the memory array region 104 includes a vertically alternating (e.g., in the Z-direction) sequence of insulative material 112 and conductive material 114 arranged in tiers 116. Each of the tiers 116 of the stack structure 110 may include a level of the conductive material 114 vertically neighboring a level of the insulative material 112. In some embodiments, the conductive material 114 is formed of and includes one or more of W, Ti, Mo, and Ru; and the insulative material 112 is formed of and includes SiO₂. For an individual tier 116 of the stack structure 110, the level of the conductive material 114 and the level of the insulative material 112 thereof may respectively exhibit a desired vertical thickness (e.g., vertical dimension in the Z-direction).

As shown in FIG. 1A, the insulative material 112 of the stack structure 110 may include a first insulative material 112A within or vertically adjacent a vertically lowermost one of the tiers 116 of the stack structure 110. The first insulative material 112A may be vertically interposed between the semiconductor material 108 and the conductive material 114 (e.g., a first conductive material 114A, described in further detail below) of the vertically lowermost one of the tiers 116 of the stack structure 110. The first insulative material 112A may vertically extend from an upper boundary (e.g., an upper surface, a top surface) of the semiconductor material 108 to a lower boundary (e.g., a lower surface, a bottom surface) of the conductive material 114 of the vertically lowermost one of the tiers 116 of the stack structure 110. In addition, a vertical thickness (e.g., in the Z-direction) of the first insulative material 112A may be substantially equal to or different than (e.g., greater than) a vertical thickness (e.g., in the Z-direction) of the insulative material 112 of respective other ones of the tiers 116 of the stack structure 110. In some embodiments, the first insulative material 112A has a vertical thickness within a range of from about 20 nanometers (nm) to about 100 nm.

Optionally, one or more liner materials (e.g., insulative liner material(s), conductive liner material(s)) may be formed at least partially around the conductive material 114 of respective ones of the tiers 116 of the stack structure 110. The liner material(s) may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). In some embodiments, the liner material(s) comprise at least one additional conductive material employed as a seed material for the formation of the conductive material 114. In some embodiments, the liner material(s) comprise titanium nitride (TiN_{y}). In further embodiments, the liner material(s) further include aluminum oxide (AlOₓ). As a non-limiting example, AlOₓ may be formed directly adjacent the insulative material 112 of respective ones of the tiers 116 of the stack structure 110, TiN_{y} may be formed directly adjacent the AlOₓ, and W may be formed directly adjacent the TiN_{y}. For clarity and ease of understanding the description, the liner material(s) are not illustrated in FIG. 1A, but it will be understood that the liner material(s) may be disposed at least partially around the conductive material 114 of respective ones of the tiers 116 of the stack structure 110.

Still referring to FIG. 1A, the conductive material 114 of the stack structure 110 may include a first conductive material 114A within one or more relatively vertically lower tier(s) 116 (e.g., at least a relatively vertically lowermost one of the tiers 116) of the stack structure 110, and a second conductive material 114B within one or more relatively vertically higher tier(s) 116 (e.g., at least a relatively vertically highest one of the tiers 116) of the stack structure 110. The first conductive material 114A may be employed for source-side select gate (SGS) structures of the memory array region 104. The second conductive material 114B may be employed for drain-side select gate (SGD) structures of the memory array region 104. Furthermore, the conductive material 114 of some further ones of the tiers 116 of the stack structure 110 may be employed for local word line (LWL) structures (e.g., local access line structures) of the memory array region 104.

With continued reference to FIG. 1A, the cell pillar structures 118 may individually be formed of and include multiple (e.g., a plurality) materials facilitating the formation of vertically extending (e.g., in the Z-direction) strings of memory cells 126 within the memory array region 104. By way of non-limiting example, the cell pillar structures 118 may individually be formed to include an outer material stack 120, channel material 122 inwardly horizontally adjacent to the outer material stack 120, and fill material 124 inwardly horizontally adjacent to the channel material 122.

The outer material stack 120 of respective ones of the cell pillar structures 118 may include charge-blocking material, such as first dielectric oxide material (e.g., SiOₓ, such as SiO₂; AlOₓ, such as Al₂O₃); charge-trapping material, such as dielectric nitride material (e.g., SiN_{y}, such as Si₃N₄); and tunnel dielectric material, such as second oxide dielectric material (e.g., SiOₓ, such as SiO₂). The tunnel dielectric material may be outwardly horizontally surrounded by the charge-trapping material; and the charge-trapping material may be outwardly horizontally surrounded by the charge-blocking material. In some embodiments, the outer material stack 120 of respective ones of the cell pillar structures 118 comprises an oxide-nitride-oxide (ONO) stack.

The channel material 122 of respective ones of the cell pillar structures 118 may be formed of and include semiconductor material. In some embodiments, the channel material 122 is formed of and includes semiconductor material (e.g., polycrystalline silicon) doped with at least one P-type dopant (e.g., one or more of boron, aluminum, and gallium) or at least one N-type dopant (e.g., one or more of phosphorus, arsenic, antimony, and bismuth), at an atomic dopant concentration less than or equal to about 1.0e17 dopant atoms per cubic centimeter. In additional embodiments, the channel material 122 is formed of and includes semiconductor material (e.g., polycrystalline silicon) doped with at least one P-type dopant or at least one N-type dopant, at an atomic concentration greater than about 1.0e17 dopant atoms per cubic centimeter. In further embodiments, the channel material 122 comprises an undoped semiconductor material (e.g., undoped polycrystalline silicon). In still further embodiments, the channel material 122 is formed of at least one oxide semiconductor material having a band gap larger than that polycrystalline silicon, such as a band gap larger than 1.65 electronvolts (eV). By way of non-limiting example, the channel material 122 may be formed of and include one or more of ZnₓSn_{y}O, InₓZn_{y}O, ZnₓO, InₓGa_{y}Zn_{z}O, InₓGa_{y}Si_{z}O, InₓW_{y}O, InₓO, SnₓO, TiₓO, ZnₓON_{z}, MgₓZn_{y}O, ZrₓIn_{y}Zn_{z}O, HfₓIn_{y}Zn_{z}O, SnₓIn_{y}Zn_{z}O, AlₓSn_{y}In_{z}ZnₐO, SiₓIn_{y}Zn_{z}O, AlₓZn_{y}Sn_{z}O, GaₓZn_{y}Sn_{z}O, ZrₓZn_{y}Sn_{z}O, and other similar materials. The channel material 122 may be substantially homogeneous, or the channel material 122 may be heterogeneous. As shown in FIG. 1A, the channel material 122 of an individual cell pillar structure 118 may be outwardly horizontally surrounded by the outer material stack 120 (e.g., tunnel dielectric material of the outer material stack 120) of the cell pillar structure 118.

The fill material 124 of respective ones of the cell pillar structures 118 may be formed of and include insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and air. In some embodiments, the fill material 124 is formed of and includes dielectric oxide material (e.g., SiOₓ, such as SiO₂). In additional embodiments, the fill material 124 is formed of and includes dielectric nitride material (e.g., SiN_{y}, such as Si₃N₄). The fill material 124 may be substantially homogeneous, or the fill material 124 may be heterogeneous. As shown in FIG. 1A, the fill material 124 of an individual cell pillar structure 118 is outwardly horizontally surrounded by the channel material 122 of the cell pillar structure 118.

As shown in FIG. 1A, lower vertical boundaries (e.g., in the Z-direction) of the cell pillar structures 118 may be positioned within a vertical span (e.g., a vertical extent) of the semiconductor material 108. The outer material stack 120 (e.g., the charge-trapping material thereof) of an individual cell pillar structure 118 may physically contact the semiconductor material 108 at outer horizontal boundaries and lower vertical boundaries of the cell pillar structure 118. As previously discussed, the first microelectronic device structure 100 may be free of (e.g., does not include) any conductive, lateral contact structure in contact (e.g., physical contact, electrical contact) with the channel material 122 of a respective cell pillar structure 118 thereof (e.g., horizontally extending through the outer material stack 120 of the cell pillar structure 118 and to the channel material 122 of the cell pillar structure 118) and vertically interposed between the base structure 102 and the stack structure 110 (e.g., vertically between the semiconductor material 108 and the stack structure 110).

Intersections of the cell pillar structures 118 and the conductive material 114 of some of the tiers 116 of the stack structure 110 may define vertically extending strings of memory cells 126 coupled in series with one another within the memory array region 104 of the first microelectronic device structure 100. In some embodiments, the memory cells 126 formed at the intersections of some of the conductive material 114 and the cell pillar structures 118 comprise so-called “MONOS” (metal-oxide-nitride-oxide-semiconductor) memory cells. In additional embodiments, the memory cells 126 comprise so-called “TANOS” (tantalum nitride aluminum oxide-nitride-oxide-semiconductor) memory cells, or so-called “BETANOS” (band/barrier engineered TANOS) memory cells, each of which are subsets of MONOS memory cells. In further embodiments, the memory cells comprise so-called “floating gate” memory cells including floating gates (e.g., metallic floating gates) as charge storage structures. The floating gates may horizontally intervene between central structures of the cell pillar structures 118 and the conductive material 114 of some of the tiers 116 of the stack structure 110.

Still referring to FIG. 1A, the conductive routing structures 130 of the conductive routing tier 128 may vertically overlie the cell pillar structures 118 (and, hence, the vertically extending strings of memory cells 126). At least some of the conductive routing structures 130 may be coupled to the cell pillar structures 118 and may be employed as digit line structures (e.g., bit line structures, data line structures) for the memory array region 104 of the first microelectronic device structure 100. Conductive routing structures 130 employed as digit line structures may exhibit horizontally elongate shapes extending in parallel in the Y-direction. As used herein, the term “parallel” means substantially parallel. The conductive routing structures 130 may individually be formed of and include conductive material, and may respectively be substantially homogeneous or heterogeneous. In some embodiments, the conductive routing structures 130 are individually formed of and include one or more of W, Ru, Mo, and TiNₓ.

With continued reference to FIG. 1A, contact structures 132 may be formed to vertically extend between and couple some of the conductive routing structures 130 and the cell pillar structures 118 (and, hence, the vertically extending strings of memory cells 126). The contact structures 132 may contact (e.g., physical contact, electrically contact) the channel material 122 of the cell pillar structures 118. In some embodiments, portions of the contact structures 132 vertically extend into the cell pillar structures 118. As shown in FIG. 1A, for an individual contact structure 132, a vertically lower portion of the contact structure 132 may vertically extend (e.g., in the Z-direction) beyond uppermost vertical boundaries (e.g., uppermost surfaces) of the channel material 122 of a respective cell pillar structure 118, and may be horizontally surrounded by and contact (e.g., physically contact, electrically contact) the channel material 122 of the cell pillar structure 118 at inner horizontal boundaries (e.g., inner sidewalls) of the channel material 122. In addition, for an individual contact structure 132, a vertically upper portion of the contact structure 132 may vertically overlie the vertically lower portion of the contact structure 132, and may be located vertically above uppermost boundaries of the cell pillar structure 118 (e.g., uppermost boundaries of the channel material 122 and the outer material stack 120 of the cell pillar structure 118). As shown in FIG. 1A, the vertically upper portion of an individual contact structure 132 may horizontally extend beyond horizontal boundaries of the vertically lower portion of the contact structure 132, and may contact (e.g., physically contact, electrically contact) the channel material 122 of an individual cell pillar structure 118 at the uppermost boundary (e.g., upper surface, top surface) of the channel material 122.

The contact structures 132 may respectively be formed of and include conductive material. A material composition of the contact structures 132 may be substantially the same as a material composition of the conductive routing structures 130, or the material composition of the contact structures 132 may be different than the material composition of the conductive routing structures 130. As a non-limiting example, at least a portion (e.g., at least the vertically lower portion) of each of the contact structures 132 may be formed of and include a conductively doped semiconductor material (e.g., conductively doped polycrystalline silicon). As another non-limiting example, at least a portion (e.g., at least the vertically upper portion) of each of the contact structures 132 may be formed of and include a metal material comprising one or more of at least one metal, at least one alloy, and at least one conductive metal-containing material (e.g., a conductive metal nitride, a conductive metal silicide, a conductive metal carbide, a conductive metal oxide). Each of the contact structures 132 may individually be substantially homogeneous, or one or more of the contact structures 132 may individually be substantially heterogeneous.

Still referring to FIG. 1A, the second isolation material 134 may be formed of and include insulative material. A material composition of the second isolation material 134 may be substantially the same as a material composition of the first isolation material 106, or the material composition of the second isolation material 134 may be different than the material composition of first isolation material 106. By way of non-limiting example, the second isolation material 134 may be formed of and include one or more of dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), dielectric nitride material (e.g., SiN_{y}), dielectric oxynitride material (e.g., SiOₓN_{y}), dielectric oxycarbide material (e.g., SiOₓC_{y}), hydrogenated dielectric oxycarbide material (e.g., SiCₓO_{y}H_{z}), and dielectric carboxynitride material (e.g., SiOₓC_{z}N_{y}). In some embodiments, the second isolation material 134 is formed of and includes dielectric oxide material (e.g., SiOₓ, such as SiO₂). In additional embodiments, the second isolation material 134 is formed of and includes low-K dielectric material, such as one or more of SiOₓC_{y}, SiOₓN_{y}, SiCₓO_{y}H_{z}, and SiOₓC_{z}N_{y}. The second isolation material 134 may be substantially homogeneous, or the second isolation material 134 may be heterogeneous.

Referring to FIG. 1B, a second microelectronic device structure 136 (e.g., a second wafer, a peripheral circuitry wafer) to subsequently be attached to the first microelectronic device structure 100 (FIG. 1A) may be formed. The second microelectronic device structure 136 may be formed to include a base semiconductor structure 138, transistors 142, additional conductive routing structures 144, additional contact structures 156, and third isolation material 158. The second microelectronic device structure 136 may form a peripheral circuitry region 140 of a microelectronic device to subsequently be formed using the second microelectronic device structure 136 and the first microelectronic device structure 100 (FIG. 1A), as described in further detail below. Portions of the base semiconductor structure 138, the transistors 142, the additional conductive routing structures 144, and the additional contact structures 156 of the second microelectronic device structure 136 form various peripheral devices 146 of the peripheral circuitry region 140, as also described in further detail below.

The base semiconductor structure 138 (e.g., semiconductor wafer) of the second microelectronic device structure 136 comprises a base material or construction upon which additional features (e.g., materials, structures, devices) of the second microelectronic device structure 136 are formed. The base semiconductor structure 138 may comprise a semiconductor structure, or a base semiconductor material on a supporting structure. For example, the base semiconductor structure 138 may comprise a conventional silicon substrate, or another bulk substrate comprising a semiconductor material. In some embodiments, the base semiconductor structure 138 is a silicon structure, such as a polycrystalline silicon structure. The base semiconductor structure 138 may include one or more layers, structures, and/or regions formed therein and/or thereon.

As shown in FIG. 1B, the transistors 142 of the peripheral circuitry region 140 may be formed to be vertically interposed between the additional conductive routing structures 144 and underlying portions of the base semiconductor structure 138. The transistors 142 may be formed to include conductively doped regions 148 (e.g., serving as source regions and drain regions of the transistors 142) within the base semiconductor structure 138, channel regions 150 within the base semiconductor structure 138 and respectively horizontally interposed (e.g., in the X-direction) between two (2) of the conductively doped regions 148, and gate structures 152 (e.g., gate electrodes) vertically overlying the channel regions 150. In addition, the second microelectronic device structure 136 may be formed to include dielectric material 154 (e.g., dielectric oxide material, such as SiO₂) vertically interposed between the gate structures 152 and the channel regions 150 of the transistors 142. The dielectric material 154 may be employed as dielectric gate material (e.g., dielectric oxide gate material) for the transistors 142, and may at least partially (e.g., substantially) horizontally extend on, over, or within the base semiconductor structure 138. As shown in FIG. 1B, in some embodiments, the dielectric material 154 is shared by multiple transistors 142 of the peripheral circuitry region 140.

For the transistors 142 of the peripheral circuitry region 140, the conductively doped regions 148 within the base semiconductor structure 138 may be doped with one or more desired conductivity enhancing species. In some embodiments, the conductively doped regions 148 are doped with at least one N-type dopant (e.g., one or more of phosphorus, arsenic, antimony, and bismuth). In some of such embodiments, the channel regions 150 within the base semiconductor structure 138 are doped with at least one P-type dopant (e.g., one or more of boron, aluminum, and gallium). In some other of such embodiments, the channel regions 150 within the base semiconductor structure 138 are substantially undoped. In additional embodiments, the conductively doped regions 148 are doped with at least one P-type dopant (e.g., one or more of boron, aluminum, and gallium). In some of such additional embodiments, the channel regions 150 within the base semiconductor structure 138 are doped with at least one N-type dopant (e.g., one or more of phosphorus, arsenic, antimony, and bismuth). In some other of such additional embodiments, the channel regions 150 within the base semiconductor structure 138 are substantially undoped.

The gate structures 152 may individually horizontally extend (e.g., in the Y-direction) between and be employed by multiple transistors 142 of the peripheral circuitry region 140. The gate structures 152 may individually be formed of and include conductive material, and may respectively be substantially homogeneous or heterogeneous. In some embodiments, the gate structures 152 are individually formed of and include one or more of W, Ru, Mo, and TiN_{y}.

Still referring to FIG. 1B, the additional conductive routing structures 144 of the second microelectronic device structure 136 may be formed to vertically overlie (e.g., in the Z-direction) the transistors 142 of the peripheral circuitry region 140. As shown in FIG. 1B, in some embodiments, the second microelectronic device structure 136 is formed to include multiple tiers of the additional conductive routing structures 144. By way of non-limiting example, the second microelectronic device structure 136 may be formed to include at least two tiers (e.g., at least three tiers) of the additional conductive routing structures 144. One or more of the tiers may vertically neighbor one or more other of the tiers. Different tiers of the additional conductive routing structures 144 may have different configurations (e.g., different features, different feature configurations, different feature arrangements) than one another that together facilitate desirable conductive paths within the second microelectronic device structure 136.

The additional conductive routing structures 144 of the second microelectronic device structure 136 may individually be formed of and include conductive material. By way of non-limiting example, the additional conductive routing structures 144 may individually be formed of and include one or more of at least one metal, at least one alloy, and at least one conductive metal-containing material (e.g., a conductive metal nitride, a conductive metal silicide, a conductive metal carbide, a conductive metal oxide). In some embodiments, the additional conductive routing structures 144 are individually formed of and include Cu. In additional embodiments, the additional conductive routing structures 144 are individually formed of and include W.

Still referring to FIG. 1B, the additional contact structures 156 may include first additional contact structures 156A and second additional contact structures 156B. The first additional contact structures 156A may vertically extend between and couple the transistors 142 to one or more of the additional conductive routing structures 144. The second additional contact structures 156B may vertically extend between and couple one or more of the additional conductive routing structures 144 to one or more other of the additional conductive routing structures 144. The additional contact structures 156 (including the first additional contact structures 156A and second additional contact structures 156B) may individually be formed of and include conductive material. In some embodiments, the additional contact structures 156 are individually formed of and include Cu. In additional embodiments, the additional contact structures 156 are individually formed of and include W. In further embodiments, the first additional contact structures 156A of the additional contact structures 156 are individually formed of and include first conductive material (e.g., W); and the second additional contact structures 156B of the additional contact structures 156 are individually formed of and include a second, different conductive material (e.g., Cu).

As previously mentioned, the transistors 142, the additional conductive routing structures 144, and the additional contact structures 156 form various peripheral circuitry (e.g., control logic circuitry, power management circuitry) of the peripheral circuitry region 140. For example, the transistors 142, the additional conductive routing structures 144, and the additional contact structures 156 may form various peripheral devices 146 (e.g., control logic devices, power management devices) of the peripheral circuitry region 140. In some embodiments, the peripheral devices 146 include complementary-metal-oxide-semiconductor (CMOS) circuitry. At least some of the peripheral devices 146 may be configured to control various operations of and/or manage power to features (e.g., the memory cells 126 (FIG. 1A)) of a microelectronic device (e.g., a memory device, such as a 3D NAND Flash memory device) to subsequently be formed from and using the first microelectronic device structure 100 (FIG. 1A) and the second microelectronic device structure 136 (FIG. 1B), as described in further detail below. As a non-limiting example, the peripheral devices 146 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, string drivers, page buffers, and various chip/deck peripheral circuitry. As another non-limiting example, the peripheral devices 146 may include devices configured to control column operations for arrays (e.g., memory element array(s), access device array(s)) within the memory array region 104 (FIG. 1A) of the first microelectronic device structure 100 (FIG. 1A), such as one or more (e.g., each) of decoders (e.g., local deck decoders, column decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry), I/O devices (e.g., local I/O devices), memory test devices, array multiplexers (MUX), and error checking and correction (ECC) devices. As a further non-limiting example, the peripheral devices 146 may include devices configured to control row operations for arrays (e.g., memory element array(s), access device array(s)) within the memory array region 104 (FIG. 1A) of the first microelectronic device structure 100 (FIG. 1A), such as one or more (e.g., each) of decoders (e.g., local deck decoders, row decoders), drivers (e.g., WL drivers), repair circuitry (e.g., row repair circuitry), memory test devices, MUX, ECC devices, and self-refresh/wear leveling devices.

Still referring to FIG. 1B, the third isolation material 158 may cover and surround portions of the transistors 142, the additional conductive routing structures 144, and the additional contact structures 156. The third isolation material 158 may subsequently be attached (e.g., bonded) to the second isolation material 134 (FIG. 1A) of the first microelectronic device structure 100 (FIG. 1A) in the process of forming a microelectronic device (e.g., a memory device) using the first microelectronic device structure 100 (FIG. 1A) and the second microelectronic device structure 136, as described in further detail below. A material composition of the third isolation material 158 may be substantially the same as a material composition of the second isolation material 134 (FIG. 1A), or the material composition of the third isolation material 158 may be different than the material composition of the second isolation material 134 (FIG. 1A). By way of non-limiting example, the second isolation material 134 may be formed of and include one or more of dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), dielectric nitride material (e.g., SiN_{y}), dielectric oxynitride material (e.g., SiOₓN_{y}), dielectric oxycarbide material (e.g., SiOₓC_{y}), hydrogenated dielectric oxycarbide material (e.g., SiCₓO_{y}H_{z}), and dielectric carboxynitride material (e.g., SiOₓC_{z}N_{y}). In some embodiments, the third isolation material 158 is formed of and includes dielectric oxide material, such as SiOₓ (e.g., SiO₂). In additional embodiments, the third isolation material 158 is formed of and includes low-K dielectric material, such as one or more of SiOₓC_{y}, SiOₓN_{y}, SiCₓO_{y}H_{z}, and SiOₓC_{z}N_{y}. The third isolation material 158 may be substantially homogeneous, or the third isolation material 158 may be heterogeneous.

Referring to next to FIG. 1C, following the formation of the first microelectronic device structure 100 and the separate formation of the second microelectronic device structure 136, the first microelectronic device structure 100 may be vertically inverted (e.g., flipped upside down in the Z-direction) and attached (e.g., bonded) to the second microelectronic device structure 136 to form an assembly 160. Alternatively, the second microelectronic device structure 136 may be vertically inverted (e.g., flipped upside down in the Z-direction) and attached to the first microelectronic device structure 100 to form the assembly 160. A front side (also referred to herein as a “face” side) of the first microelectronic device structure 100 may be considered to be a side (e.g., end surface) most proximate to the conductive routing structures 130, and a back side of the first microelectronic device structure 100 may be considered to be an additional side (e.g., additional end surface) relatively more distal from the conductive routing structures 130 (e.g., most proximate to the base structure 102) than the front side. In addition, a front side (also referred to herein as a “face” side) of second microelectronic device structure 136 may be considered to be a side (e.g., end surface) most proximate to the additional conductive routing structures 144, and a back side of the second microelectronic device structure 136 may be considered to be an additional side (e.g., additional end surface) relatively more distal from the additional conductive routing structures 144 (e.g., most proximate to the base semiconductor structure 138) than the front side. Accordingly, in the configuration shown in FIG. 1C, the assembly 160 may be formed to have a “front-to-front” (F2F) (also referred to herein as “face-to-face”) arrangement of the first microelectronic device structure 100 relative to the second microelectronic device structure 136.

Attaching the first microelectronic device structure 100 to the second microelectronic device structure 136 may couple at least some of conductive routing structures 130 (e.g., digit line structures) of the memory array region 104 to at least some of the additional conductive routing structures 144 of the peripheral circuitry region 140. Attaching the first microelectronic device structure 100 to the second microelectronic device structure 136 may also attach (e.g., bond) the second isolation material 134 of the first microelectronic device structure 100 to the third isolation material 158 of the second microelectronic device structure 136. In FIG. 1C, vertical boundaries of the first microelectronic device structure 100 relative to the second microelectronic device structure 136 prior to the attachment of the first microelectronic device structure 100 to the second microelectronic device structure 136 to form the assembly 160 are depicted by the dashed line A-A.

The first microelectronic device structure 100 may be attached to the second microelectronic device structure 136 through dielectric-to-dielectric (e.g., oxide-to-oxide, oxide-to-oxycarbide, oxide-to-oxynitride, oxide-to-carboxynitride, oxycarbide-to-oxycarbide, oxynitride-to-oxynitride, nitride-to-nitride) bonding alone or through a combination of dielectric-to-dielectric bonding and conductor-to-conductor (e.g., metal-to-metal) bonding. For example, the first microelectronic device structure 100 and the second microelectronic device structure 136 may be brought into physical contact with one another at an interface, and then the resulting assembly may be exposed to a temperature greater than or equal to about 400° C. (e.g., within a range of from about 400° C. to about 800° C., greater than about 800° C.) to at least form dielectric-to-dielectric bonds between the second isolation material 134 of the first microelectronic device structure 100 and the third isolation material 158 of the second microelectronic device structure 136. In some embodiments, the attachment process also forms conductor-to-conductor (e.g., metal-to-metal) bonds between at least some of the conductive routing structures 130 of the first microelectronic device structure 100 and at least some of the additional conductive routing structures 144 of the second microelectronic device structure 136. The first microelectronic device structure 100 may be attached to the second microelectronic device structure 136 without a bond line.

Referring next to FIG. 1D, after attaching the first microelectronic device structure 100 to the second microelectronic device structure 136 to form the assembly 160, the base structure 102 (FIG. 1C), the first isolation material 106, at least an upper portion of the semiconductor material 108 (FIG. 1C), and upper portions of the cell pillar structures 118 are removed to expose (e.g., uncover) portions of respective cell pillar structures 118. As shown in FIG. 1D, the material removal process may expose surfaces (e.g., upper surfaces) of remaining portions of the outer material stack 120, the channel material 122, and the fill material 124 of respective ones of the cell pillar structures 118.

As shown in FIG. 1D, in some embodiments, the semiconductor material 108 (FIG. 1C) is substantially completely removed by the material removal process. Accordingly, the material removal process may expose portions (e.g., an upper surface) of the first insulative material 112A previously covered by the semiconductor material 108 (FIG. 1C). Following the material removal process, uppermost boundaries (e.g., upper surfaces, top surfaces) of remaining portions of the first insulative material 112A and respective ones of the cell pillar structures (e.g., of the outer material stack 120, the channel material 122, and the fill material 124 thereof) may be substantially coplanar with one another.

In additional embodiments, the semiconductor material 108 (FIG. 1C) is only partially (e.g., less than completely) removed by the material removal process. In such embodiments, an uppermost boundary (e.g., an upper surface, a top surface) of a remaining portion of the semiconductor material 108 (FIG. 1C) may be vertically positioned (e.g., in the Z-direction) at or below uppermost boundaries (e.g., upper surfaces, top surfaces) of remaining portions of the cell pillar structures 118. For example, the uppermost boundary of the remaining portion of the semiconductor material 108 may be formed to be substantially coplanar with uppermost boundaries of remaining portions of respective ones of the cell pillar structures 118 (e.g., of the outer material stack 120, the channel material 122, and the fill material 124 thereof). As another example, the uppermost boundary of the remaining portion of the semiconductor material 108 may be formed to vertically underlie uppermost boundaries of remaining portions of respective ones of the cell pillar structures 118 (e.g., of one or more of the outer material stack 120, the channel material 122, and the fill material 124 thereof).

The base structure 102 (FIG. 1C), the first isolation material 106 (FIG. 1C), at least the upper portion of the semiconductor material 108 (FIG. 1C), and the upper portions of the cell pillar structures 118 may be removed using one or more of at least one abrading process (e.g., at least one CMP process) and at least one etching process (e.g., at least one wet etching process and/or at least one dry etching process). In some embodiments, the base structure 102 (FIG. 1C), the first isolation material 106 (FIG. 1C), at least the upper portion of the semiconductor material 108 (FIG. 1C), and the upper portions of the cell pillar structures 118 are removed through a CMP process.

Before proceeding to the discussion of FIGS. 1E and 1F, it will be understood that subsequent description of previously introduced feature(s) (e.g., region(s), material(s), structure(s), device(s))—whether provided with reference to a subsequent figure or to the same figure following processing already described with respect to that figure—refers to remaining portion(s) or resulting portion(s) of the same feature(s) following completion of one or more processing act(s) previously described with respect to one or more preceding figures and/or the same figure, unless otherwise specified.

Referring next to FIG. 1E, top sections of the outer material stack 120 and the fill material 124 of respective ones of the cell pillar structures 118 may be selectively removed relative to top sections 122A of the channel material 122 of the respective ones of the cell pillar structures 118. The material removal process may expose inner side surfaces (e.g., inner sidewalls) and outer side surfaces (e.g., outer sidewalls) of the top sections 122A of the channel material 122 of the respective ones of the cell pillar structures 118. The material removal process may also completely remove remaining portions of the semiconductor material 108 (FIG. 1C), if any, to expose the first insulative material 112A thereunder. In some embodiments, the material removal process also partially (e.g., less than completely) removes the first insulative material 112A. Accordingly, the material removal process may reduce a vertical thickness of the first insulative material 112A. In additional embodiments, the first insulative material 112A is substantially maintained during the material removal process, such that the material removal process does not substantially reduce the vertical thickness of the first insulative material 112A. As shown in FIG. 1E, the top sections 122A of the channel material 122 of the respective ones of the cell pillar structures 118 may vertically overlie (e.g., in the Z-direction) an uppermost boundary (e.g., an upper surface, a top surface) of the first insulative material 112A, as well as uppermost boundaries (e.g., upper surfaces, top surfaces) of the outer material stack 120 and the fill material 124 of respective ones of the cell pillar structures 118.

As shown in FIG. 1A, for an individual cell pillar structure 118, the top section 122A of the channel material 122 thereof may vertically extend (e.g., in the Z-direction) beyond the uppermost boundary (e.g., the upper surface, the top surface) of the first insulative material 112A by a first vertical height H₁. The top section 122A may be considered to exhibit the first vertical height H₁. The first vertical height H₁ may, for example, be within a range of from about 10 nanometers (nm) to about 50 nm, such as from about 15 nm to about 50 nm, from about 20 nm to about 50 nm, or from about 30 nm to about 50 nm. In some embodiments wherein the material removal process partially removes the first insulative material 112A, the first vertical height H₁ is substantially equal to a vertical height of an upper portion of the first insulative material 112A removed (e.g., etched away) by the material removal process. In some additional embodiments wherein the material removal process completely removes a remaining portion of the semiconductor material 108 (FIG. 1C) and partially removes the first insulative material 112A, the first vertical height H₁ is substantially equal to a combined vertical height of the remaining portion of the semiconductor material 108 (FIG. 1C) and an upper portion of the first insulative material 112A collectively removed by the material removal process. In some further embodiments wherein the first insulative material 112A is substantially maintained during the material removal process, the first vertical height H₁ is substantially equal to a vertical height of a remaining portion of the semiconductor material 108 (FIG. 1C) completely removed (e.g., etched away) by the material removal process.

In some embodiments, following the material removal process, the uppermost boundaries of the first insulative material 112A, the outer material stack 120 of the respective ones of the cell pillar structures 118, and the fill material 124 of the respective ones of the cell pillar structures 118 are substantially coplanar with one another. In additional embodiments, uppermost boundaries of one or more of the first insulative material 112A, the outer material stack 120 of the respective ones of the cell pillar structures 118, and the fill material 124 of the respective ones of the cell pillar structures 118 are vertically offset from (e.g., are not substantially coplanar with) the uppermost boundaries of one or more others of the first insulative material 112A, the outer material stack 120 of the respective ones of the cell pillar structures 118, and the fill material 124 of the respective ones of the cell pillar structures 118. For example, the uppermost boundary of the first insulative material 112A may be vertically offset from (e.g., vertically overlies, vertically underlies) the uppermost boundary of the fill material 124 of the respective ones of the cell pillar structures 118. As another example, the uppermost boundary of the first insulative material 112A may be vertically offset from (e.g., vertically overlies, vertically underlies) the uppermost boundary of at least one component (e.g., at least the charge storage material) of the outer material stack 120 of the respective ones of the cell pillar structures 118. As a further example, the uppermost boundary of the fill material 124 of the respective ones of the cell pillar structures 118 may be vertically offset from (e.g., vertically overlies, vertically underlies) the uppermost boundary of at least one component (e.g., at least the charge storage material) of the outer material stack 120 of the respective ones of the cell pillar structures 118. In some embodiments, the uppermost boundary of the fill material 124 of the respective ones of the cell pillar structures 118 is vertically below each of the uppermost boundary of the first insulative material 112A and the uppermost boundary of the outer material stack 120 of the respective ones of the cell pillar structures 118.

As shown in FIG. 1E, the material removal process may form openings 162 (e.g., recesses, blind vias) vertically above and within horizontal areas of the fill material 124 of the respective ones of the cell pillar structures 118. An individual opening 162 may have horizontal boundaries defined by an inner side surface (e.g., an inner sidewall) of the channel material 122 of a respective one of the cell pillar structures 118, and a lower vertical boundary defined by an upper surface of the fill material 124 of the respective one of the cell pillar structures 118. An individual opening 162 may vertically extend from an uppermost boundary vertically positioned at an uppermost boundary of the channel material 122 (e.g., of the top section 122A thereof) of a respective one of the cell pillar structures 118 to a lowermost boundary at, above, or below the uppermost boundary of the first insulative material 112A. As shown in FIG. 1E, in some embodiments, the lowermost boundary of an individual opening 162 is substantially coplanar with the uppermost boundary of the first insulative material 112A. In additional embodiments, the lowermost boundary of an individual opening 162 is at a vertical position 163 below the uppermost boundary of the first insulative material 112A. The vertical position 163 may be at or above a lowermost vertical boundary of the first conductive material 114A vertically neighboring the first insulative material 112A. By way of non-limiting example, the vertical position 163 may be above an upper vertical boundary (e.g., an upper surface) of the first conductive material 114A, such as within a vertical span of the first insulative material 112A; or may be at or below the upper vertical boundary of the first conductive material 114A, such as within a vertical span of the first conductive material 114A. An individual opening 162 may, for example, have a second vertical height H₂ within a range of from about 10 nm to about 200 nm, such as from about 15 nm to about 180 nm, from about 20 nm to about 160 nm, or from about 30 nm to about 150 nm. The second vertical height H₂ of an individual opening 162 may be less than, greater than, or substantially equal to the first vertical height H₁ of the top section 122A of the channel material 122 of an individual cell pillar structure 118.

Referring next to FIG. 1F, a low work function (LWF) metal material 164 may be formed on exposed portions of the cell pillar structures 118 and the first insulative material 112A, and a high work function (HWF) metal material 166 may be formed on the LWF metal material 164. As described in further detail below, the LWF metal material 164 and the HWF metal material 166 may each physically contact one or more surfaces of the channel material 122 of respective ones of the cell pillar structures 118.

The LWF metal material 164 may be formed to directly contact (e.g., physically contact) side surfaces (e.g., inner side surface, outer side surfaces) of the channel material 122 of the respective ones of the cell pillar structures 118. For example, as shown in FIG. 1F, the LWF metal material 164 may physically contact portions (e.g., upper portions) of the inner side surfaces and the outer side surfaces of the channel material 122 of the respective ones of the cell pillar structures 118. In addition, the LWF metal material 164 may be formed to directly contact (e.g., physically contact) upper surfaces of the first insulative material 112A, as well as upper surfaces of the outer material stack 120 and the fill material 124 of the respective ones of the cell pillar structures 118. The LWF metal material 164 may at least partially (e.g., substantially) fill respective ones of the openings 162 (FIG. 1E). In addition, the LWF metal material 164 may substantially horizontally surround and vertically extend substantially completely across the top sections 122A of the channel material 122 of the respective ones of the cell pillar structures 118.

An upper boundary (e.g., an upper surface) of the LWF metal material 164 may be at or below a vertical position (e.g., in the Z-direction) of an upper boundary (e.g., an upper surface) of the channel material 122 of respective ones of the cell pillar structures 118. As shown FIG. 1F, in some embodiments, the upper boundary of the LWF metal material 164 is substantially coplanar with the upper boundary of the channel material 122 of the respective ones of the cell pillar structures 118. In additional embodiments, the upper boundary of the LWF metal material 164 is at least partially vertically below the upper boundary of the channel material 122 of the respective ones of the cell pillar structures 118. An upper surface of the channel material 122 of the respective ones of the cell pillar structures 118 may be substantially free of the LWF metal material 164 thereon. In some embodiments, the upper boundary of the LWF metal material 164 is substantially planar. In additional embodiments, the upper boundary of the LWF metal material 164 is at least partially non-planar (e.g., may exhibit curvature in one or more sections thereof).

The LWF metal material 164 may comprise a metal material (e.g., one or more of a metal; an alloy; and a conductive metal-containing material, such one or more of a conductive metal nitride, a conductive metal silicide, a conductive metal carbide) having a work function (WF) less than or equal to about 4.7 electronvolts (eV), such as within a range of from about 3.6 eV to about 4.7 eV, from about 4.0 eV to about 4.7 eV, from about 4.0 eV to about 4.5 eV, or from about 4.0 eV to about 4.4 eV. In some embodiments, the LWF metal material 164 has a WF that is relatively closer to 4.0 eV than is a WF of the HWF metal material 166. By way of non-limiting example, the LWF metal material 164 may be formed of and include one or more of nickel (Ni), tungsten (W), molybdenum (Mo), copper (Cu), cobalt (Co), chromium (Cr), vanadium (Va), tantalum (Ta), ruthenium (Ru), titanium nitride (TiNₓ), tantalum nitride (TaNₓ), molybdenum nitride (MoNₓ), zirconium nitride (ZrNₓ), hafnium nitride (HfNₓ), molybdenum silicide (MoSiₓ), tungsten silicide (WSiₓ), nickel silicide (NiSiₓ), cobalt silicide (CoSiₓ), tantalum silicide (TaSiₓ), and titanium silicide (TaSiₓ).

Still referring to FIG. 1F, the HWF metal material 166 may be formed to directly contact (e.g., physically contact) an upper surface (e.g., a top surface) of the channel material 122 of respective ones of the cell pillar structures 118. For example, the HWF metal material 166 may vertically overlie, substantially horizontally extend across, and physically contact the upper surface of the channel material 122 of the respective ones of the cell pillar structures 118. In addition, the HWF metal material 166 may be formed to directly contact (e.g., physically contact) and substantially cover an upper surface of the LWF metal material 164. A lower boundary of the HWF metal material 166 may have a geometry corresponding to (e.g., mirroring) a topography at least partially defined by upper boundaries (e.g., upper surfaces) of the LWF metal material 164 and the channel material 122 of the respective ones of the cell pillar structures 118. In some embodiments, the lower boundary of the HWF metal material 166 is substantially planar. In additional embodiments, the lower boundary of the HWF metal material 166 is at least partially non-planar. In addition, an upper boundary of the HWF metal material 166 may be formed to be substantially planar, or may be formed to be at least partially non-planar. In some embodiments, the upper boundary of the HWF metal material 166 is substantially planar.

The HWF metal material 166 may comprise a metal material (e.g., one or more of a metal; an alloy; and a conductive metal-containing material, such one or more of a conductive metal nitride, a conductive metal silicide, a conductive metal carbide) having a WF greater than or equal to about 4.3 eV, such as within a range of from about 4.4 eV to about 5.3 eV, from about 4.4 eV to about 5.1 eV, from about 4.6 eV to about 5.3 eV, or from about 4.7 eV to about 5.1 eV, or from about 4.0 eV to about 4.4 eV. In some embodiments, the HWF metal material 166 has a WF that is relatively closer to 5.0 eV than is a WF of the LWF metal material 164. By way of non-limiting example, the LWF metal material 164 may be formed of and include one or more of gold (Au), palladium (Pd), iridium (Ir), nickel (Ni), tungsten (W), molybdenum (Mo), copper (Cu), cobalt (Co), chromium (Cr), ruthenium (Ru), titanium nitride (TiNₓ), tantalum nitride (TaNₓ), molybdenum nitride (MoNₓ), zirconium nitride (ZrNₓ), hafnium nitride (HfNₓ), molybdenum silicide (MoSiₓ), tungsten silicide (WSiₓ), nickel silicide (NiSiₓ), cobalt silicide (CoSiₓ), tantalum silicide (TaSiₓ), and titanium silicide (TaSiₓ).

In additional embodiments, rather than forming each of the LWF metal material 164 and the HWF metal material 166, a single (e.g., only one) mid-tier work function (MWF) metal material may be employed. The MWF metal material may have a WF within an WF overlap range of the LWF metal material 164 and the HWF metal material 166. The MWF metal material may, for example, have a WF within a range of from about 4.3 eV to about 4.7 eV, such as from about 4.4 eV to about 4.7 eV, or from about 4.4 eV to about 4.6 eV. By way of non-limiting example, the MWF metal material may be formed of and include one or more of nickel (Ni), tungsten (W), molybdenum (Mo), copper (Cu), cobalt (Co), chromium (Cr), ruthenium (Ru), titanium nitride (TiNₓ), tantalum nitride (TaNₓ), molybdenum nitride (MoNₓ), zirconium nitride (ZrNₓ), molybdenum silicide (MoSiₓ), tungsten silicide (WSiₓ), nickel silicide (NiSiₓ), cobalt silicide (CoSiₓ), tantalum silicide (TaSiₓ), and titanium silicide (TaSiₓ). If employed, the single MWF metal material may have geometric configuration corresponding to (e.g., substantially the same as) a combined geometric configuration of the LWF metal material 164 and the HWF metal material 166. Accordingly, interactions (e.g., physical contact, electrical contact) of the single MWF metal material with the cell pillar structures 118 (including the channel material 122 thereof) and the first insulative material 112A may correspond to (e.g., be substantially the same as) a combination of the interactions of the LWF metal material 164 and the HWF metal material 166 with the cell pillar structures 118 (including the channel material 122 thereof) and the first insulative material 112A.

Still referring to FIG. 1F, the LWF metal material 164 and the HWF metal material 166 are shorted together. The LWF metal material 164 and the HWF metal material 166 may effectively form an active body structure for an array of the vertically extending strings of memory cells 126. In embodiments wherein a single MWF metal material is employed in place of the LWF metal material 164 and the HWF metal material 166, the single MWF metal material may alone serve as the active body structure for the array of the vertically extending strings of memory cells 126.

Forming the LWF metal material 164 in physical contact with the channel material 122 of each of the cell pillar structures 118 forms first Schottky contacts 168 having rectifying characteristics at junctions (e.g., interfaces) of the LWF metal material 164 and the channel material. The relatively low WF of the LWF metal material 164 facilitates efficient electron injection into the channel material 122 under appropriate bias conditions, such as those applied during program and read operations. This promotes strong n-type conduction in the channel region, allowing electrons to flow readily through the channel when a memory cell 126 is in a conductive (ON) state. As a result, the first Schottky contacts 168 ensure sufficient drive current and low access resistance, which improves the overall speed and reliability of program and read operations. Furthermore, the lower injection barrier at the junction (e.g., interface) of the LWF metal material 164 and the channel material 122 reduces voltage stress during operation, which can enhance device longevity and help preserve the integrity of the channel material 122 and the outer material stack 120 of respective ones of the cell pillar structures 118 over time.

In addition, forming the HWF metal material 166 in physical contact with the channel material 122 of each of the cell pillar structures 118 establishes second Schottky contacts 170 having rectifying characteristics at junctions (e.g., interfaces) of the HWF metal material 166 and the channel material 122. The second Schottky contacts 170 may also facilitate body erase operations on the vertical extending strings of memory cells 126. During erase operations, the second Schottky contacts 170 may be biased, at least partially based on the WF of the HWF metal material 166, with a voltage (e.g., greater than or equal to 3 V) sufficient to effectuate a predetermined erase current (which can be within a range of a few nanoamperes (nA) per cell pillar structure 118 to a few thousand nA per cell pillar structure 118). The relatively high WF of the HWF metal material 166 facilitates efficient hole injection into the channel material 122 of the cell pillar structures 118 under erase bias conditions. Such hole injection helps accumulate positive charge in a body region of respective ones of the cell pillar structures 118, which raises channel potential and enhances band-to-band tunneling or other mechanisms used to remove stored electrons from charge storage regions (e.g., from regions of the charge storage material of the outer material stack 120), thereby improving the efficiency and uniformity of the body erase operation. Moreover, the ability to achieve more complete and uniform charge removal during erase helps maintain consistent threshold voltages (Vₜ) across the memory cells 126, reducing Vₜ variability and minimizing over-erase conditions. This contributes to improved cell-to-cell uniformity and reduces stress on the tunnel dielectric material of the outer material stack 120 of respective one of the cell pillar structures 118, which in turn enhances endurance by mitigating cumulative damage over repeated program/erase cycles.

In additional embodiments wherein a single MWF metal material is employed instead of the LWF metal material 164 and the HWF metal material 166, forming the MWF metal material in physical contact with the channel material 122 of each of the cell pillar structures 118 establishes different Schottky contacts at junctions (e.g., interfaces) of the MWF metal material and the channel material 122. The MWF metal material, having a WF within the WF overlap range of the LWF metal material 164 and the HWF metal material 166, may permit the different Schottky contacts to support desirable read/program and body erase operations without employing a distinct LWF metal material 164 and a distinct HWF metal material 166. Under read and program bias conditions, the MWF metal material may facilitate electron injection into the channel material 122 to permit channel conduction and memory cell 126 access. Under elevated erase bias conditions, the MWF metal material may facilitate hole injection into body regions of the cell pillar structures 118 to raise the channel potential and assist with charge removal from charge storage regions (e.g., from regions of the charge storage material of the outer material stack 120). Although the carrier injection efficiency may be less than that of a configuration employing the LWF metal material 164 and the HWF metal material 166, appropriate biasing may compensate for this, allowing the different Schottky contacts to provide sufficient performance for both forward conduction and erase functionality. Thus, employing a single MWF metal material may reduce process complexity while still supporting robust Vₜ control, endurance, and operational reliability across the array of the vertically extending strings of memory cells 126.

As shown in FIG. 1F, the formation of the LWF metal material 164 and the HWF metal material 166 (or the formation of the MWF metal material) may effectuate the formation of a microelectronic device 172 (e.g., a memory device, such as a 3D NAND Flash memory device). The microelectronic device 172 is configured for body erase operations on the vertically extending strings of memory cells 126, and includes the peripheral circuitry region 140 (including the various features thereof shown in FIG. 1F, and formed through the processing described with reference to FIG. 1B) and the memory array region 104 (including the various features thereof shown in FIG. 1F, and formed through the processing described with reference to FIGS. 1A and 1C through 1F) vertically overlying and operatively associated with the peripheral circuitry region 140.

The configuration of the microelectronic device 172 facilitates efficient body erase operations as well as desirable program and read operations on the vertical extending strings of memory cells 126, while also permitting the peripheral circuitry region 140 to be vertically offset from (e.g., vertical under) and at least partially within a horizontal area of the memory array region 104. This arrangement supports a compact and scalable design, such as a CMOS under array (“CuA”) configuration or a CMOS above array (“CaA”) configuration, rather than the CMOS outside array (“CoA”) configuration commonly associated with conventional body erase architectures. Body erase operations for the microelectronic device 172 offer advantages over gate-induce-drain-leakage (GIDL)-assisted erase approaches, such as relatively relaxed margins for SGS (e.g., the first conductive material 114A) and SGD (e.g., the second conductive material 114B) on current (Iₒₙ) and off current (I_{off}), and relatively reduced SGS and SGD trapping during erase operations (e.g., since a relatively large bias offset between SGS/SGD and source/digit lines are not necessary). Furthermore, unlike conventional microelectronic devices designed for body erase operations, the microelectronic device 172 does not require epitaxial semiconductive material (e.g., epitaxial silicon) vertically underlying and in contact with cell pillar structures to facilitate body erase operations. The configuration of the microelectronic device 172 employs Schottky contacts that facilitate both electron and hole injection under respective biasing conditions. This alleviates the need for an epitaxial semiconductive material for body contact, simplifying fabrication and providing high-density 3D integration without compromising erase efficiency or read/program performance.

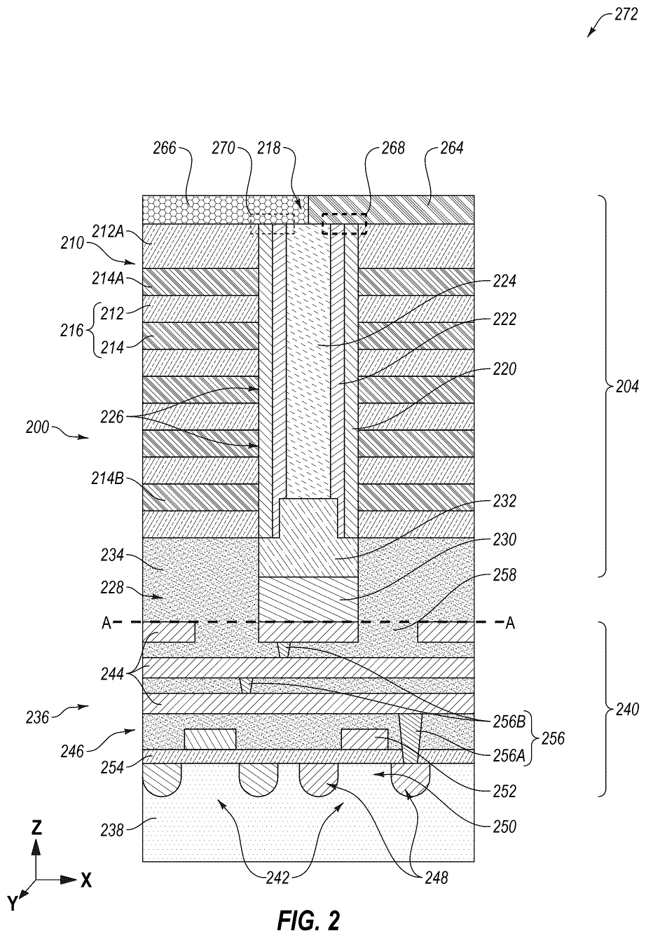

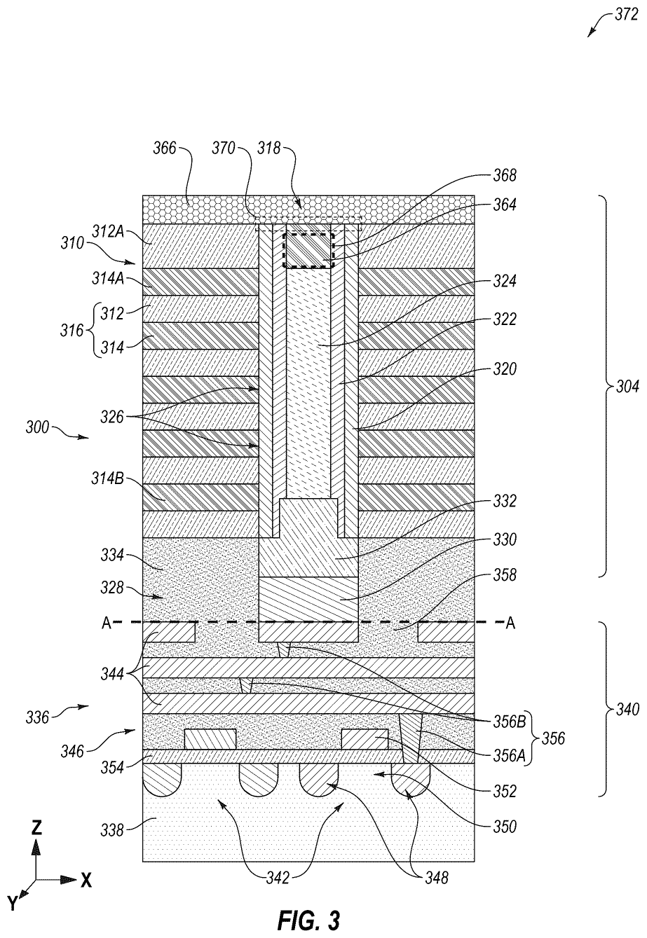

In additional embodiments, some of the processing (e.g., processing acts, processing stages) previously described herein with reference to FIGS. 1A through 1F may modified to form additional microelectronic devices of the disclosure having different configurations than the microelectronic device 172 (FIG. 1F). For example, FIGS. 2 and 3 are simplified, partial vertical cross-sectional views of a microelectronic device 272 (FIG. 2) and a microelectronic device 372 (FIG. 3) formed in accordance with additional methods of the disclosure. The method of forming the microelectronic device 272 (FIG. 2) and the method of forming the microelectronic device 372 (FIG. 3) may include the processing (e.g., processing acts, processing stages) previously described herein with reference to FIGS. 1A through 1D, but additional processing following the processing previously described herein with reference to FIG. 1D may be modified relative to that previously described herein with reference to FIGS. 1E and 1F.

It will be understood that throughout the FIGS. 2 and 3 and the associated description, features (e.g., regions, materials, structures, circuitry, devices) functionally similar to respective features previously described with reference to one or more of FIGS. 1A through 1F are referred to with similar reference numerals incremented by 100. To avoid repetition, not all features shown in FIGS. 2 and 3 are described in detail herein. Rather, unless described otherwise below, a feature in one or more of FIGS. 2 and 3 designated by a reference numeral that is a 100 increment of the reference numeral of a feature previously described with reference to one or more of FIGS. 1A through 1F will be understood to be substantially similar to and have substantially the same advantages as the previously described feature. As a non-limiting example, in FIGS. 2 and 3, a stack structure 210 (FIG. 2) and a stack structure 310 (FIG. 3) may respectively be substantially similar to the stack structure 110 previously described herein with reference to one or more of FIGS. 1A and 1C through 1F. As another non-limiting example, in FIGS. 2 and 3, a second microelectronic device structure 236 (FIG. 2) and a second microelectronic device structure 336 (FIG. 3) may respectively be substantially similar to the second microelectronic device structure 136 previously described herein with reference to one or more of FIGS. 1B through 1F.

Referring to FIG. 2, the microelectronic device 272 may be formed to include different configurations of the cell pillar structures 218, the LWF metal material 264, and the HWF metal material 266 thereof as compared to respective configurations of the cell pillar structures 118 (FIG. 1F), the LWF metal material 164 (FIG. 1F), and the HWF metal material 166 (FIG. 1F) of the microelectronic device 172 (FIG. 1F). For example, the material removal process previously described with reference to FIG. 1E may be omitted, and the LWF metal material 264 and the HWF metal material 266 may be formed at substantially a same vertical position (e.g., in the Z-direction) as one another. As described in further detail below, the LWF metal material 264 and the HWF metal material 266 may horizontally neighbor one another (e.g., in the X-direction), and may each vertically overlie (e.g., in the Z-direction) and directly contact (e.g., physically contact) an upper surface of the channel material 222 of respective ones of the cell pillar structures 218.

Following the processing stage previously described with reference to FIG. 1D, the LWF metal material 264 and the HWF metal material 266 may respectively be formed on upper surfaces of the first insulative material 212A and the cell pillar structures 218 without first vertically recessing at least the outer material stack 220 and the fill material 224 of respective ones of the cell pillar structures 218 relative to the channel material 222 of the respective ones of the cell pillar structures 218. For an individual cell pillar structure 218, the LWF metal material 264 may horizontally overlap (e.g., in the X-direction) and physically contact a first portion of an upper surface of the cell pillar structure 218 (including first portions of upper surfaces of the outer material stack 220, the channel material 222, and the fill material 224 thereof), and the HWF metal material 266 may horizontally overlap (e.g., in the X-direction) and physically contact a second portion of the upper surface of the cell pillar structure 218 (including second portions of the upper surfaces of the outer material stack 220, the channel material 222, and the fill material 224 thereof). The LWF metal material 264 and the HWF metal material 266 may also horizontally overlap (e.g., in the X-direction) and physically contact different portions of an upper surface of the first insulative material 212A than one another. In addition, at least one side surface of the LWF metal material 264 vertically overlap (e.g., in the Z-direction) and physically contact at least one opposing side surface of the HWF metal material 266.

As shown in FIG. 2, in some embodiments, for an individual cell pillar structure 218, the LWF metal material 264 horizontally overlaps (e.g., in the X-direction) and physically contacts about one-half (½) of the cell pillar structure 218, and the HWF metal material 266 horizontally overlaps (e.g., in the X-direction) and physically contacts and an other about one-half (½) of the cell pillar structure 218. Accordingly, an interface between the LWF metal material 264 and HWF metal material 266 in the X-direction may be substantially aligned with a horizontal centerline of the cell pillar structure 218 in the X-direction. In additional embodiments, the LWF metal material 264 and the HWF metal material 266 individually horizontally overlap the cell pillar structure 218 differently than shown in FIG. 2 (e.g., greater than about one-half (½) of the cell pillar structure 218, less than about one-half (½) of the cell pillar structure 218), so long as the LWF metal material 264 horizontally overlaps (e.g., in the X-direction) and physically contacts a portion of an upper surface of the channel material 222 of the cell pillar structure 218 and the HWF metal material 266 horizontally overlaps (e.g., in the X-direction) and physically contacts a different portion of the upper surface of the channel material 222 of the cell pillar structure 218. In addition, vertical thicknesses (e.g., in the Z-direction) of the LWF metal material 264 and HWF metal material 266 may substantially equal to one another, or may be different than one another.

A material composition of the LWF metal material 264 may be substantially the same as the material composition of the LWF metal material 164 (FIG. 1F), and may facilitate first Schottky contacts 268 that are functionally substantially the same as the first Schottky contacts 168 (FIG. 1F). In addition, a material composition of the HWF metal material 266 may be substantially the same as the material composition of the HWF metal material 166 (FIG. 1F), and may facilitate second Schottky contacts 270 that are functionally substantially the same as the second Schottky contacts 170 (FIG. 1F). However, as shown in FIG. 2, the first Schottky contacts 268 and the second Schottky contacts 270 of the microelectronic device 272 may have substantially the same vertical position (e.g., in the Z-direction) as one another.

In additional embodiments, rather than forming each of the LWF metal material 264 and the HWF metal material 266, a single (e.g., only one) MWF metal material may be employed. The single MWF metal material may have geometric configuration corresponding to (e.g., substantially the same as) a combined geometric configuration of the LWF metal material 264 and the HWF metal material 266. Accordingly, interactions (e.g., physical contact, electrical contact) of the single MWF metal material with the cell pillar structures 218 (including the channel material 222 thereof) and the first insulative material 212A may correspond to (e.g., be substantially the same as) a combination of the interactions of the LWF metal material 264 and the HWF metal material 266 with the cell pillar structures 218 (including the channel material 222 thereof) and the first insulative material 212A. In such embodiments, a material composition of the MWF metal material may be substantially the same as the material composition of the MWF metal material previously described herein with reference to FIG. 1F, and may facilitate different Schottky contacts that are functionally substantially the same as the different Schottky contacts previously described herein with reference to FIG. 1F.

Referring to FIG. 3, the microelectronic device 372 may be formed to include different configurations of the cell pillar structures 318, the LWF metal material 364, and the HWF metal material 366 thereof as compared to respective configurations of the cell pillar structures 118 (FIG. 1F), the LWF metal material 164 (FIG. 1F), and the HWF metal material 166 (FIG. 1F) of the microelectronic device 172 (FIG. 1F). For example, the material removal process previously described with reference to FIG. 1E may be modified to vertically recess the fill material 324 of respective ones of the cell pillar structures 318 without substantially vertically recessing other features (e.g., the outer material stack 320, the channel material 322). Thereafter, the LWF metal material 364 may be formed and substantially confined within the openings (e.g., equivalents to the openings 162 (FIG. 1E)), and then the HWF metal material 366 may be formed on upper surfaces of the LWF metal material 364, the cell pillar structures 318, and the first insulative material 312A. As described in further detail below, the LWF metal material 364 and the HWF metal material 366 may vertically neighbor one another (e.g., in the Z-direction); the LWF metal material 364 may directly contact (e.g., physically contact) an inner side surface of the channel material 322 of respective ones of the cell pillar structures 318; and the HWF metal material 366 may directly contact (e.g., physically contact) an upper surface of the channel material 322 of the respective ones of the cell pillar structures 318.

As shown in FIG. 3, the LWF metal material 364 may be substantially horizontally confined within a horizontal area of the fill material 324 of respective ones of the cell pillar structures 318, and may vertically extend from an upper boundary (e.g., an upper surface) of the fill material 324 to or proximate an upper boundary (e.g., an upper surface) of the channel material 322 of the respective ones of the cell pillar structures 318. For an individual cell pillar structure 318, the LWF metal material 364 may physically contact an upper surface of the fill material 324 thereof, and may also physically contact inner side surfaces of the channel material 322 thereof. An upper surface of the first insulative material 312A and upper surfaces of the outer material stack 320 and the channel material 322 of respective ones of the cell pillar structure 318 may individually be substantially free of the LWF metal material 264 thereon. As shown in FIG. 3, in some embodiments, upper boundaries (e.g., upper surfaces) of the LWF metal material 364 are substantially coplanar with an upper boundary (e.g., an upper surface) of the first insulative material 312A and upper boundaries (e.g., upper surfaces) of the outer material stack 320 and the channel material 322 of respective ones of the cell pillar structures 318. In additional embodiments, upper boundaries of the LWF metal material 364 are vertically offset from (e.g., are vertically below) one or more of an upper boundary of the first insulative material 312A and upper boundaries of the outer material stack 320 and/or the channel material 322 of respective ones of the cell pillar structure 318.

The HWF metal material 366 may vertically overlie, physically contact, and horizontally extend across upper surfaces of the first insulative material 312A, the LWF metal material 364, and the outer material stack 320 and the channel material 322 of respective ones of the cell pillar structure 318. For an individual cell pillar structure 318, the HWF metal material 366 may physically contact and substantially cover an upper surface of the channel material 322 thereof. As shown in FIG. 3, in some embodiments, a lower boundary (e.g., a lower surface) of the HWF metal material 366 is substantially planar. The lower boundary of the HWF metal material 366 may, for example, be substantially coplanar with an upper boundary (e.g., an upper surface) of the LWF metal material 364, an upper boundary (e.g., an upper surface) of first insulative material 312A, and upper boundaries (e.g., upper surfaces) of the outer material stack 320 and the channel material 322 of respective ones of the cell pillar structures 318. In further embodiments, the lower boundary of the HWF metal material 366 is at least partially non-planar. In addition, an upper boundary (e.g., an upper surface) of the HWF metal material 366 may be substantially planar, or may be at least partially non-planar.

A material composition of the LWF metal material 364 may be substantially the same as the material composition of the LWF metal material 164 (FIG. 1F), and may facilitate first Schottky contacts 368 that are functionally substantially the same as the first Schottky contacts 168 (FIG. 1F). In addition, a material composition of the HWF metal material 366 may be substantially the same as the material composition of the HWF metal material 166 (FIG. 1F), and may facilitate second Schottky contacts 370 that are functionally substantially the same as the second Schottky contacts 170 (FIG. 1F).

In additional embodiments, rather than forming each of the LWF metal material 364 and the HWF metal material 366, a single (e.g., only one) MWF metal material may be employed. The single MWF metal material may have geometric configuration corresponding to (e.g., substantially the same as) a combined geometric configuration of the LWF metal material 364 and the HWF metal material 366. Accordingly, interactions (e.g., physical contact, electrical contact) of the single MWF metal material with the cell pillar structures 318 (including the channel material 322 thereof) and the first insulative material 312A may correspond to (e.g., be substantially the same as) a combination of the interactions of the LWF metal material 364 and the HWF metal material 366 with the cell pillar structures 318 (including the channel material 322 thereof) and the first insulative material 312A. In such embodiments, a material composition of the MWF metal material may be substantially the same as the material composition of the MWF metal material previously described herein with reference to FIG. 1F, and may facilitate different Schottky contacts that are functionally substantially the same as the different Schottky contacts previously described herein with reference to FIG. 1F.

Thus, a microelectronic device according to embodiments of the disclosure includes a stack structure, a cell pillar structure, metal material, and additional metal material. The stack structure includes tiers vertically stacked relative to one another and respectively including conductive material and insulative material vertically neighboring the conductive material. The cell pillar structure vertically extends through the stack structure and includes a fill material, a channel material horizontally surrounding the fill material, and an outer material stack horizontally surrounding the channel material. The metal material is vertically above the conductive material of an uppermost one of the tiers of the stack structure and is in physical contact with the channel material of the cell pillar structure. The metal material has a work function within a range of from about 3.6 eV to about 4.7 eV. The additional metal material is vertically above the conductive material of the uppermost one of the tiers of the stack structure and is in physical contact with the channel material of the cell pillar structure. The additional metal material has an additional work function within a range of from about 4.4 eV to about 5.3 eV.

Furthermore, in accordance with embodiments of the disclosure, a method of forming microelectronic device includes forming a first microelectronic device structure including one or more of control logic circuitry and power management circuitry. A second microelectronic device structure is formed and includes a semiconductor material overlying a base structure; a stack structure overlying the semiconductor material and including conductive material vertically alternating with insulative material; and a cell pillar structure vertically extending through the stack structure and into the semiconductor material, the cell pillar structure including a channel material horizontally interposed between an outer material stack and a dielectric fill material. The second microelectronic device structure is bonded to the first microelectronic device structure to form an assembly. After forming the assembly, the base structure, the semiconductor material, and a portion of the cell pillar structure are removed to partially expose the channel material of the cell pillar structure. A metal material is formed in physical contact with at least one exposed portion of the channel material of the cell pillar structure and has a work function within a range of from about 3.6 eV to about 4.7 eV. An additional metal material is formed in physical contact with at least one additional exposed portion of the channel material of the cell pillar structure and has an additional work function within a range of from about 4.4 eV to about 5.3 eV.

Moreover, a memory device according to embodiments of the disclosure includes a memory array region and a peripheral circuitry region vertically offset from and horizontally overlapping the memory array region. The memory array region includes a stack structure, an active body structure, and a cell pillar structure. The stack structure includes a vertically alternating sequence of conductive material and insulative material. The active body structure is vertically offset from the stack structure and includes: a first metal material having a first work function less than or equal to about 4.7 eV; and a second metal material having a second work function greater than or equal to about 4.4 eV. The cell pillar structure includes semiconductor material extending through the stack structure and contacting the active body structure to form: a first Schottky contact at an interface between the semiconductor material and the first metal material; and a second Schottky contact at an additional interface between the semiconductor material and the second metal material. The peripheral circuitry region includes control logic devices in electrical communication with the cell pillar structure.

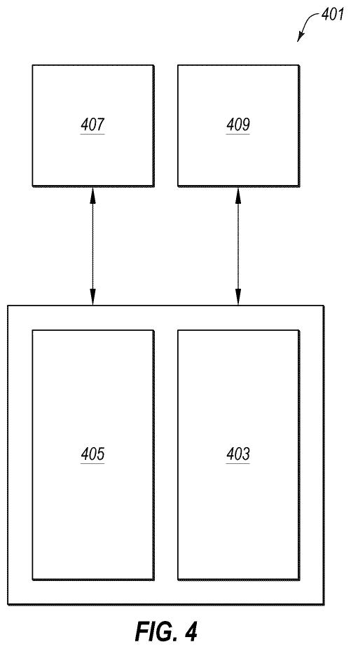

Microelectronic devices (e.g., the microelectronic device 172 (FIG. 1F), the microelectronic device 272 (FIG. 2), the microelectronic device 372 (FIG. 3)) in accordance with embodiments of the disclosure may be used in embodiments of electronic systems of the disclosure. For example, FIG. 4 is a block diagram of an illustrative electronic system 401 according to embodiments of disclosure. The electronic system 401 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 401 includes at least one memory device 403. The memory device 403 may comprise, for example, a microelectronic device (e.g., the microelectronic device 172 (FIG. 1F), the microelectronic device 272 (FIG. 2), the microelectronic device 372 (FIG. 3)) previously described herein. The electronic system 401 may further include at least one electronic signal processor device 405 (often referred to as a “microprocessor”). The electronic signal processor device 405 may, optionally, include a microelectronic device (e.g., the microelectronic device 172 (FIG. 1F), the microelectronic device 272 (FIG. 2), the microelectronic device 372 (FIG. 3)) previously described herein. While the memory device 403 and the electronic signal processor device 405 are depicted as two (2) separate devices in FIG. 4, in additional embodiments, a single (e.g., only one) memory/processor device having the functionalities of the memory device 403 and the electronic signal processor device 405 is included in the electronic system 401. In such embodiments, the memory/processor device may include a microelectronic device (e.g., the microelectronic device 172 (FIG. 1F), the microelectronic device 272 (FIG. 2), the microelectronic device 372 (FIG. 3)) previously described herein. The electronic system 401 may further include one or more input devices 407 for inputting information into the electronic system 401 by a user, such as, for example, a mouse or other pointing device, a keyboard, a touchpad, a button, or a control panel. The electronic system 401 may further include one or more output devices 409 for outputting information (e.g., visual or audio output) to a user such as, for example, a monitor, a display, a printer, an audio output jack, a speaker, etc. In some embodiments, the input device 407 and the output device 409 may comprise a single touchscreen device that can be used both to input information to the electronic system 401 and to output visual information to a user. The input device 407 and the output device 409 may communicate electrically with one or more of the memory device 403 and the electronic signal processor device 405.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a stack structure comprising tiers vertically stacked relative to one another and respectively comprising conductive material and insulative material vertically neighboring the conductive material;
a cell pillar structure vertically extending through the stack structure and comprising:
a fill material;
a channel material horizontally surrounding the fill material; and
an outer material stack horizontally surrounding the channel material;
metal material vertically above the conductive material of an uppermost one of the tiers of the stack structure and in physical contact with the channel material of the cell pillar structure, the metal material having a work function within a range of from about 3.6 eV to about 4.7 eV; and
additional metal material vertically above the conductive material of the uppermost one of the tiers of the stack structure and in physical contact with the channel material of the cell pillar structure, the additional metal material having an additional work function within a range of from about 4.4 eV to about 5.3 eV.

2. The microelectronic device of claim 1, wherein:
the metal material physically contacts an inner side surface of the channel material of the cell pillar structure; and
the additional metal material physically contacts upper surfaces of the metal material and the channel material of the cell pillar structure.

3. The microelectronic device of claim 2, wherein the metal material is substantially horizontally confined within a horizontal area of the fill material of the cell pillar structure.

4. The microelectronic device of claim 2, wherein the metal material also physically contacts:
an outer side surface of the channel material of the cell pillar structure; and
an upper surface of the outer material stack of the cell pillar structure.

5. The microelectronic device of claim 4, wherein a lower boundary of a portion of the metal material in physical contact with the inner side surface of the channel material of the cell pillar structure is vertically offset from an additional lower boundary of an additional portion of the metal material in physical contact with the outer side surface of the channel material of the cell pillar structure.

6. The microelectronic device of claim 1, wherein:
the metal material physically contacts a first portion of an upper surface of the channel material of the cell pillar structure; and
the additional metal material vertically overlaps the metal material and physically contacts a second portion of the upper surface of the channel material of the cell pillar structure.

7. The microelectronic device of claim 1, wherein the work function of the metal material is relatively closer to 4.0 eV and relatively farther from 5.0 eV than is the additional work function of the additional metal material.

8. The microelectronic device of claim 1, wherein the work function of the metal material and the additional work function of the additional metal material are respectively within a range of from about 4.4 eV to about 4.7 eV.

9. The microelectronic device of claim 7, wherein the work function of the metal material and the additional work function of the additional metal material are substantially the same as one another.

10. The microelectronic device of claim 1, further comprising control logic circuitry vertically below and coupled to the cell pillar structure.

11. A method of forming a microelectronic device, comprising:
forming a first microelectronic device structure comprising one or more of control logic circuitry and power management circuitry;
forming a second microelectronic device structure comprising:
a semiconductor material overlying a base structure;
a stack structure overlying the semiconductor material and comprising conductive material vertically alternating with insulative material; and
a cell pillar structure vertically extending through the stack structure and into the semiconductor material, the cell pillar structure comprising a channel material horizontally interposed between an outer material stack and a dielectric fill material;
bonding the second microelectronic device structure to the first microelectronic device structure to form an assembly;
after forming the assembly, removing the base structure, the semiconductor material, and a portion of the cell pillar structure to partially expose the channel material of the cell pillar structure;
forming metal material in physical contact with at least one exposed portion of the channel material of the cell pillar structure and having a work function within a range of from about 3.6 eV to about 4.7 eV; and
forming additional metal material in physical contact with at least one additional exposed portion of the channel material of the cell pillar structure and having an additional work function within a range of from about 4.4 eV to about 5.3 eV.

12. The method of claim 11, wherein:
removing the base structure, the semiconductor material, and a portion of the cell pillar structure comprises vertically recessing at least the dielectric fill material of the cell pillar structure relative to the channel material of the cell pillar structure;
forming metal material in physical contact with at least one exposed portion of the channel material comprises forming the metal material in physical contact with an exposed upper portion of an inner sidewall of the channel material; and
forming additional metal material in physical contact with at least one additional exposed portion of the channel material comprises forming the additional metal material in physical contact with an exposed upper surface of the channel material.

13. The method of claim 12, wherein forming the additional metal material further comprises forming the additional metal material on a top surface of the metal material.

14. The method of claim 12, wherein:
removing the base structure, the semiconductor material, and a portion of the cell pillar structure further comprises vertically recessing the outer material stack of the cell pillar structure relative to the channel material of the cell pillar structure; and
forming the metal material in physical contact with at least one exposed portion of the channel material further comprises forming the metal material in physical contact with an exposed top portion of an outer sidewall of the channel material.

15. The method of claim 14, further comprising forming an upper surface of a remaining portion of the dielectric fill material of the cell pillar structure to vertically underlie a top surface of a remaining portion of the outer material stack of the cell pillar structure.

16. The method of claim 11, wherein:
forming metal material in physical contact with at least one exposed portion of the channel material comprises forming the metal material in physical contact with a first portion of an exposed upper surface of the channel material; and
forming additional metal material in physical contact with at least one additional exposed portion of the channel material comprises forming the additional metal material in physical contact with a second portion of the exposed upper surface of the channel material.

17. The method of claim 16, further comprising forming the additional metal material to vertically overlap and have substantially a same vertical thickness as the metal material, the additional metal material horizontally neighboring and in physical contact with the metal material.

18. The method of claim 11, wherein bonding the second microelectronic device structure to the first microelectronic device structure comprises:
vertically inverting one of the second microelectronic device structure and the first microelectronic device structure relative to an other of the second microelectronic device structure and the first microelectronic device structure; and
bonding the second microelectronic device structure to the first microelectronic device structure through one or more of dielectric-to-dielectric bonds and metal-to-metal bonds.

19. A memory device, comprising:
a memory array region comprising:
a stack structure comprising a vertically alternating sequence of conductive material and insulative material;
an active body structure vertically offset from the stack structure and comprising:
a first metal material having a first work function less than or equal to about 4.7 eV; and
a second metal material having a second work function greater than or equal to about 4.4 eV;
a cell pillar structure comprising semiconductor material extending through the stack structure and contacting the active body structure to form:
a first Schottky contact at an interface between the semiconductor material and the first metal material; and
a second Schottky contact at an additional interface between the semiconductor material and the second metal material; and
a peripheral circuitry region vertically offset from and horizontally overlapping the memory array region, the peripheral circuitry region comprising control logic devices in electrical communication with the cell pillar structure.

20. The memory device of claim 19, wherein:
the first work function of the first metal material of the active body structure is within a range of from about 3.6 eV to about 4.5 eV; and
the second work function of the second metal material of the active body structure is within a range of from about 4.6 eV to about 5.3 eV.
